(19) United States
(12) Patent Application Publication
(10) Pub. No.: US 2002/0139968 A1
(43) Pub. Date: Oct. 3, 2002

(54) Semiconductor light emitting element and method for producing the same

(76) Inventors: Masafumi Kondo, Soraku-gun (JP); Mototaka Taneya, Nara-shi (JP)

Correspondence Address: Madeline Johnston, Morrison & Foerster LLP, 755 Page Mill Rd., Palo Alto, CA, 94304-1018, US

(21) Appl. No.: 10/113,492

(22) Filed: Mar. 29, 2002

(30) Foreign Application Priority Data
Mar. 29, 2001 (JP) 2001-097677

(51) Int. Cl. H01L 29/06

(52) U.S. Cl. 257/10; 257/13

(57) ABSTRACT

A semiconductor light emitting element, includes: a substrate; a first conductive semiconductor layer formed on the substrate; a strained emission layer formed on the first conductive semiconductor layer; and a second conductive semiconductor layer formed on the strained emission layer, wherein the strained emission layer includes: an element other than a constituent element of the substrate; and a rare earth element.

### BACKGROUND OF THE INVENTION

1. Field of the Invention

The present invention relates to a semiconductor light emitting element formed using a III-V group nitride semiconductor and a method for producing the same. Specifically, the present invention relates to a semiconductor light emitting element having a double hetero structure formed by using GaN, InGaN, GaNAs, GaNP, etc., and a method for producing the same.

2. Description of the Related Art

In a semiconductor light emitting element formed using GaN, which is a III-V group nitride semiconductor, when a rare earth element is added to a strained emission layer formed of GaN of the light emitting element, a PL emission of a shorter wavelength (477 to 1914 nm) as compared with that of a strained emission layer formed of undoped GaN to which a rare earth element has not been added, and an EL emission generated due to a MIS structure are observed (Handout for the 19th seminar of the 162nd committee on Short-wavelength Opto-electronic Devices of Japan Society for the Promotion of Science (11.12.9), Compound Semiconductor 6(1) 48 (2000)).

A rare earth element has an inner shell electron formed of an open f-shell, and an external shell electron, such as a closed s-shell, a closed p-shell, or the like, which is located outside of the f-shell so as to shield the inner shell electron. Thus, a semiconductor light emitting element including a rare earth element can produce an emission spectrum between f-levels, the spectrum having a narrow sharp half-width and not being influenced by the surrounding environment. The emission between f-levels produced by the semiconductor light emitting element including a rare earth element is an interlevel emission which can be regarded as an atomic level emission. Thus, a semiconductor light emitting element whose emission intensity and emission wavelength are very stable against temperature can be obtained.

In existing blue and green semiconductor light emitting elements, InGaN is used as a material of a strained emission layer. In such a strained emission layer, composition separation between GaN and InN readily occurs, and accordingly, it is difficult to form a crystal having a predefined composition that generates an emission spectrum at a predetermined emission wavelength. Thus, in the existing strained emission layer, there is some difficulty in obtaining desired uniformity and reproducibility of crystals. In order to address such a problem, Japanese Laid-Open Patent Publication No. 2000-91703 discloses that GaN including a rare earth element added thereto is used in a strained emission layer.

However, in a strained emission layer formed of GaN including a rare earth element, even if the rare earth element is added to GaNat a concentration of several percent, the position at which the peak of X-ray intensity in the X-ray diffraction pattern is obtained is substantially the same as a position at which the peak of X-ray intensity in the X-ray diffraction pattern for undoped GaN not including a rare earth element is obtained. Conversely, the half-width of the X-ray intensity for GaN including a rare earth element is about two times greater than that for GaN not including a rare earth element. Such an increase in the half-width of the X-ray intensity for GaN including a rare earth element may deteriorate crystallinity, and accordingly, a non-emission center in the crystal increases. As a result, the emission efficiency may deteriorate.

### SUMMARY OF THE INVENTION

According to one aspect of the present invention, a semiconductor light emitting element includes: a substrate; a first conductive semiconductor layer formed on the substrate; a strained emission layer formed on the first conductive semiconductor layer; and a second conductive semiconductor layer formed on the strained emission layer, wherein the strained emission layer includes: an element other than a constituent element of the substrate; and a rare earth element.

In one embodiment of the present invention, the substrate is an electrically conductive substrate.

In another embodiment of the present invention, the element other than a constituent element of the substrate is at least one of a III-group element and a V-group element.

In still another embodiment of the present invention, the strained emission layer is formed of InₓGa₁₋ₓN where 0<x <0.5.

In still another embodiment of the present invention, the strained emission layer is formed of GaN₁₋ₓAsₓ where 0<x<0.1.

In still another embodiment of the present invention, the strained emission layer is formed of GaN₁₋ₓPₓ where 0<x<0.15.

In still another embodiment of the present invention, the strained emission layer is formed of GaN₁₋ₓAsₓ or GaN₁₋ₓPₓ and contains In.

In still another embodiment of the present invention, the rare earth element included in the strained emission layer is at least one selected from a group consisting of Er, Eu, Ho, Nd, Pr, Tm, and Yb.

According to another aspect of the present invention, a method for producing a semiconductor light emitting element includes steps of: forming a first conductive nitride semiconductor layer having a first conduction type, at a first growth temperature, on a nitride semiconductor substrate having the first conduction type; forming a strained emission layer, at a second growth temperature which is different from the first growth temperature, on the first or second conductive nitride semiconductor layer; and forming a second conductive nitride semiconductor layer having a second conduction type, at a third growth temperature which is different from the first and second growth temperatures, on the strained emission layer.

Thus, the invention described herein makes possible the advantages of (1) providing a semiconductor light emitting element having high emission efficiency where the provision of a rare earth element, which forms an emission center, is increased so as to improve the transfer efficiency of an injected current from a primary portion of an emission layer to the rare earth element, and (2) providing a method for producing such a semiconductor light emitting element.

These and other advantages of the present invention will become apparent to those skilled in the art upon reading and understanding the following detailed description with reference to the accompanying figures.

### BRIEF DESCRIPTION OF THE DRAWINGS

FIG. 1 is a cross-sectional view showing a structure of a semiconductor light emitting element according to an embodiment of the present invention.

FIG. 2 is a graph showing a relationship between the ratio of In in a strained emission layer, which is formed of a composition of InₓGa₁₋ₓN (0≦x≦1) including a rare earth element Eu (europium), and the emission intensity obtained from Eu contained in the composition of InₓGa₁₋ₓN (for wavelengths of 620 nm or smaller).

### DESCRIPTION OF THE PREFERRED EMBODIMENTS

A strained emission layer formed of GaN including several percent (in composition ratio) of a rare earth element was subjected to crystal evaluation using Rutherford Backscattering Spectroscopy (RBS). It was confirmed that a very small amount of the rare earth element is present at a lattice position of a primary constituent crystal of GaN, and 50% or more of the added rare earth element is present at interstitial positions. As a result, it was confirmed that, in a GaN layer produced by a conventional technique including a large amount of a rare earth element which does not contribute to emission, the large amount of the rare earth element is present at interstitial positions, and accordingly, the crystallinity was deteriorated, thus the emission efficiency was decreased due to an increase of non-emission centers.

FIG. 2 is a graph showing a relationship between the ratio of In in a strained emission layer, which is formed of a composition of InₓGa₁₋ₓN (0≦x≦1) including a rare earth element Eu, and the emission intensity obtained from Eu contained in the composition of InₓGa₁₋ₓN (for wavelengths of 620 nm or smaller). The emission intensity obtained from Eu contained in InₓGa₁₋ₓN shown in the graph of FIG. 2 is normalized by using the emission intensity obtained from GaN containing Eu. The present inventors confirmed that the emission intensity obtained from Eu contained in InₓGa₁₋ₓN is greater than that obtained from GaN containing Eu when the ratio of In in InₓGa₁₋ₓN is in the range of 0<x<0.5. The emission intensity obtained from Eu contained in InₓGa₁₋ₓN is greater than that obtained from GaN containing Eu by one magnitude (i.e., by ten or more times) when the ratio of In in InₓGa₁₋ₓN is in the range of 0.05≦x≦0.30.

From the above, the following is determined. The bond distance of the Eu—N bond is greater than that of the Ga—N bond due to a difference in electro negativity between Eu and Ga. Adding In to a primary constituent crystal of GaN means adding strain to an emission layer with respect to GaN. As a result of addition of In to GaN, the bond distance between a III-group element and a nitride atom is increased, and the potential of Eu at a III-group lattice position (lattice point) becomes stable. Therefore, the uptake efficiency of Eu into the III-group lattice position is improved. When the amount of In added to GaN is increased such that the In ratio x is greater than 0.5, nitrogen vacancies which may be generated due to InN are increased. The nitrogen vacancies are readily bonded to III-group elements so as to form potentially-stable defects (i.e., defects having a stable potential). As a result, the amount of Eu taken up into the III-group lattice positions is decreased, while the occurrence of non-emission centers is increased due to the nitrogen vacancies, whereby the emission intensity obtained from Eu contained in InₓGa₁₋ₓN is significantly decreased.

Then, it was confirmed that, in the case where GaN₁₋ₓAsₓ was used in a strained emission layer, the emission intensity of the strained emission layer was increased by adding a very small amount of As to the strained emission layer, as compared with a conventional semiconductor light emitting element, so long as the ratio of As(x) in the composition GaN₁₋ₓAsₓ was 0.1 or smaller. In the case where the ratio of As(x) was greater than 0.1, GaAs cubic crystals and GaN hexagonal crystals were non-uniformly mixed so that a desired crystal of GaN₁₋ₓAsₓ was not obtained, and the emission intensity was rapidly decreased. As a result, in a semiconductor light emitting element where GaN₁₋ₓAsₓ is used in a strained light emitting layer, when the ratio of As(x) in GaN₁₋ₓAsₓ is in the range of 0.005<x≦0.05, the emission intensity is increased by about two times as compared with that of the conventional light emitting element.

In the case where GaN₁₋ₓPₓ was used in a strained emission layer, the emission intensity of the strained emission layer was increased as compared with the conventional semiconductor light emitting element by adding a very small amount of P to the strained emission layer, so long as the ratio of P(x) in the composition GaN₁₋ₓPₓ was 0.15 or smaller. In the case where the ratio of P(x) was greater than 0.15, GaP cubic crystals and GaN hexagonal crystals were non-uniformly mixed so that a desired crystal of GaN₁₋ₓPₓ was not obtained, and the emission intensity was rapidly decreased. As a result, in a semiconductor light emitting element where GaN₁₋ₓPₓ is used in a strained light emitting layer, when the ratio of P(x) in GaN₁₋ₓPₓ is in the range of 0.005<x≦0.15, the emission intensity is increased by about three times as compared with that of the conventional light emitting element.

Further, in the case where a composition of GaN₁₋ₓAsₓ or GaN₁₋ₓPₓ is used in the strained emission layer, the As or P content in the composition can be reduced by the addition of In. Furthermore, due to addition of In, non-uniform mixture of GaAs cubic crystals and GaN hexagonal crystals, or non-uniform mixture of GaP cubic crystals and GaN hexagonal crystals, which causes a decrease in the emission efficiency of a semiconductor light emitting element, can be suppressed.

Since a rare earth element added to the strained light emitting element has an inner shell electron formed of an open f-shell, and an external shell electron, such as a closed s-shell, a closed p-shell, or the like, which is located outside of the f-shell so as to shield the inner shell electron, a semiconductor light emitting element including the strained emission layer to which a rare earth element is added can produce emission spectrum between f-levels, the spectrum having a narrow sharp half-width and not being influenced by the surrounding environment. Since this emission is an interlevel emission which can be regarded as an atomic level emission, a semiconductor light emitting element whose emission intensity and emission wavelength are very stable against temperature can be obtained. Examples of such a rare earth element include Er (erbium), Eu (europium), Ho (holmium), Nd (neodymium), Pr (praseodymium), Tm (thulium), and Yb (ytterbium). These rare earth elements can also be used as phosphors and act as an emission center. Further, an ion of such a rare earth element is excited in a multiphase fashion so as to generate light having a shorter wavelength as compared with an excited light. That is, such a rare earth element is an up-conversion element which increasingly converts the frequency of light. Furthermore, it was confirmed that a semiconductor light emitting element including a strained emission layer to which two or more of the above rare earth elements were added produced two or more types of light having different wavelengths. Furthermore, it was confirmed that, in the case where a white color LED (light emitting diode) formed of a semiconductor light emitting element in which a rare earth element is added to a strained light emitting layer thereof was used as a backlight, the color rendering characteristic of the backlight was improved because such a white color LED can produce multiple types of light having different wavelengths.

The present invention was conceived based on such determinations.

### EMBODIMENT 1

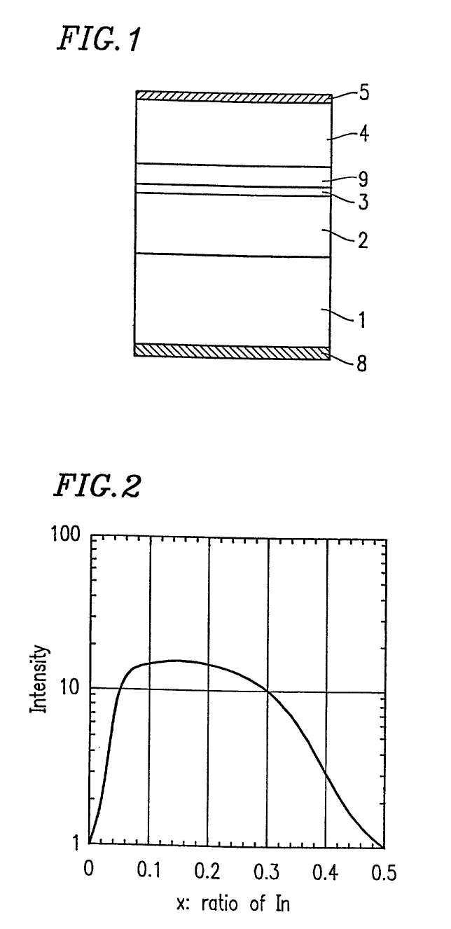

FIG. 1 is a cross-sectional view showing a structure of a semiconductor light emitting element according to embodiment 1 of the present invention. A nitride semiconductor light emitting element shown in FIG. 1 includes an electrically conductive n-type GaN substrate 1 produced by using Hydride Vapor Phase Epitaxy (Hydride VPE) which uses a hydride as a source material gas. The nitride semiconductor light emitting element includes, on the n-type GaN substrate 1, a first cladding layer 2 of n-type GaN, a strained emission layer 3 of Mg-doped InₓGa₁₋ₓN, a carrier blocking layer 9 of p-type AlGaN, and a second cladding layer 4 of p-type GaN, which are formed in this order using a MOCVD (Metal Organic Chemical Vapor Deposition) method. A transparent electrode 5 is formed over the second cladding layer 4, Over a part of the transparent electrode 5, a bonding electrode (not shown) is provided. Over the under surface of the n-type GaN substrate 1 with respect to the first cladding layer 2, an electrode 8 is formed.

In this embodiment, the n-type GaN substrate 1 is used as a substrate of the light emitting element. However, the same effects of the present invention can be obtained even when a sapphire substrate is used. In the case where a sapphire substrate is used, a GaN buffer layer is formed over the sapphire substrate before the n-type GaN first cladding layer 2 is formed thereon. In embodiment 1, the Mg-doped InₓGa₁₋ₓN strained emission layer 3 contains a rare earth element Er (erbium) added thereto and is an In_{0.35}Ga_{0.65}N layer. The thickness of the strained emission layer 3 is 30 Å. The Mg-doped, p-type GaN second cladding layer 4 has a large resistance value. Thus, even if a positive hole, which will be a current component, is injected only through the bonding electrode (not shown) into a portion of the second cladding layer 4, the current density may not be uniform over the entire strained emission layer 3. Therefore, the thin transparent electrode 5 is provided over the entire surface of the second cladding layer 4 between the bonding electrode (not shown) and the p-type GaN second cladding layer 4, so that a large amount of emitted light can be obtained from the strained emission layer 3.

However, in the case where a non-conductive substrate such as a sapphire substrate is used, it is difficult to obtain a perfectly uniform current density over the entire surface of the strained emission layer 3. For example, in this embodiment where a rare earth element is used as an emission source, a sharp, high peak is obtained as the emission intensity distribution pattern. Thus, more uniform and more efficient emission can be obtained with a conductive substrate as compared with a non-conductive substrate, such as a sapphire substrate.

The electrode 8 formed under the n-type GaN substrate 1 is formed of a metal. It is preferable that the electrode 8 includes any of Al, Ti, Zr, Hf, V, and Nb. The transparent electrode 5 formed over the p-type GaN second cladding layer 4 is formed of a metal film having a thickness of 20 nm or smaller. It is preferable that the transparent electrode 5 includes any of Ta, Co, Rh, Ni, Pd, Pt, Cu, Ag, and Au.

Next, a method for producing the semiconductor light emitting element according to this embodiment is described. At the first step, a sapphire substrate having a (0001) face is washed, and an undoped GaN film is formed over the sapphire substrate as an underlying layer by using a MOCVD method according to the procedure described below.

The washed sapphire substrate is placed in a MOCVD apparatus, and cleaned at a high temperature of about 1100° C. in an H₂ atmosphere. Thereafter, the temperature is decreased to 600° C., and NH₃ and TMG (trimethyl gallium) are supplied at 5 liters/min and 20 mol/min, respectively, while supplying a carrier gas of H₂ at 10 liters/min, so as to form a low-temperature GaN buffer layer having a thickness of about 20 nm. Then, the supply of TMG is stopped, and the temperature is increased to about 1050° C. Then, TMG is supplied at 100 mol/min for 1 hour so as to form a undoped GaN film having a thickness of about 3 μm. Thereafter, the supply of TMG and NH₃ is stopped, and the temperature is decreased to room temperature. Then, the sapphire substrate on which an undoped GaN film has been formed as an underlying layer is removed from the MOCVD apparatus.

In this embodiment, the low-temperature GaN buffer layer is used as the low-temperature buffer layer, but the present invention is not limited to a GaN buffer layer. Even when an AlN buffer layer or GaAlN buffer layer produced from TMA (trimethyl aluminum), TMG (trimethyl gallium), NH₃, or the like, is used, the same effects of the present invention can be obtained.

Then, over the undoped GaN underlying layer formed in this way on the sapphire substrate, a striped growth suppression film is formed so as to have a thickness of about 0.2 μm, a stripe width of 7 μm, and a stripe interval of 10 μm, where the growth suppression film has the function of preventing generation of a crack in a subsequently formed thick film. Over the growth suppression film, a flat surfaced GaN thick film is selectively grown by the Hydride VPE method. The growth suppression film is formed of a dielectric, such as SiO₂, SiNₓ, W, or the like, or a metal having a high melting point. In this embodiment, a SiO₂ film as the growth suppression film formed by sputtering is shaped by photolithography or etching.

Hereinafter, a method for growing the GaN thick layer based on the Hydride VPE method is described. After the striped growth suppression film has been formed over the undoped GaN underlying layer, the resultant structure is installed into the Hydride VPE apparatus. The temperature of the structure is increased to about 1050° C., while supplying N₂ carrier gas and NH₃ each at 5 liters/min into the Hydride VPE apparatus. Thereafter, GaCl is supplied to the resultant structure at 100 cc/min, so that growth of a GaN thick film begins. GaCl is generated by supplying HCl gas to Ga metal kept at about 850° C. Further, impurity doping can be optionally performed during the growth of the GaN thick film using a separately-provided impurity doping pipeline which is formed so as to reach the vicinity of the structure installed in the Hydride VPE apparatus. In this embodiment, supply of monosilane (SiH₄) at 200 nmol/min (Si impurity concentration: about 3.8×10¹⁸/cm³) is began simultaneously with the start of growth of the GaN thick film, in order to form a Si-doped GaN thick film.

The above growth process is performed for 6 hours, whereby a GaN thick film having a thickness of about 700 μm is formed. Then, the sapphire substrate is removed by polishing or the like, so as to obtain the n-type GaN substrate 1.

On the n-type GaN substrate 1, a semiconductor light emitting element is formed by a MOCVD method according to embodiment 1 of the present invention. At a first step, then-type GaN substrate 1 is installed in a MOCVD apparatus. The temperature of the n-type GaN substrate 1 is increased to about 1050° C. while supplying N₂ (carrier gas) and NH₃ each at 5 liters/min. After the temperature of the substrate 1 has been increased to about 1050° C., the carrier gas is switched from N₂ to H₂, and TMG (trimethyl gallium) is supplied at 100 μmol/min and SiH₄ (monosilane) is supplied at 10 nmol/min, so as to form the n-type GaN first cladding layer 2 having a thickness of about 1 μm. Thereafter, supply of TMG is stopped, the carrier gas is switched again from H₂ to N₂, and the temperature is decreased to 700° C. TMI (trimethyl indium) as an indium source is supplied at 68.5 μmol/min, and TMG is supplied at 12.8 μmol/min, so as to form the In_{0.35}Ga_{0.65}N strained emission layer 3. During formation of the strained emission layer 3, a source gas containing a rare earth element Er, (C₂H₅)₃Er (i.e., Cp3Er), is supplied in order to add the rare earth element Er to the strained emission layer 3.

After the strained emission layer 3 containing the rare earth element Er has been formed, supply of TMG, TMI, and Cp3Er is stopped, and the temperature is increased again to 1000° C. The carrier gas is switched again from N₂ to H₂. TMG is supplied at 27 μmol/min, TMA (trimethyl aluminum) is supplied at 15 μmol/min, and biscyclopentadienyl magnesium (Cp2Mg) is supplied at 10 nmol/min as a source gas of a p-type impurity element Mg so as to form the p-type Ala_{0.2}Ga_{0.8}N carrier blocking layer 9 having a thickness of 50 nm. After the carrier blocking layer 9 has been formed, supply of TMA is stopped, so that a p-type GaN layer is formed over the carrier blocking layer 9 having a thickness of 100 nm. Then, Cp2Mg is supplied at 30 nmol/min so as to form, over the p-type GaN layer, the p-type GaN second cladding layer 4 having a thickness of 20 nm, whereby a primary part of a semiconductor light emitting element of embodiment 1 is completed.

After the primary part of the semiconductor light emitting element of embodiment 1 has been fabricated, the supply of TMG and Cp2Mg is stopped, and the temperature is decreased to room temperature. Then, the resultant semiconductor light emitting element is removed from the MOCVD apparatus. Thereafter, the thickness of the n-type GaN substrate 1 is appropriately adjusted, and a transparent electrode 5 is formed over the upper surface of the p-type GaN second cladding layer 4. On a portion of the upper surface of the second cladding layer 4, a bonding electrode (not shown) is formed. Further, an electrode 8 is formed on the lower surface of the GaN substrate 1, whereby a semiconductor light emitting element of the present invention is completed.

As the substrate on which the layered structure including the strained emission layer 3 is grown, a substrate made of a material which has a thermal expansion coefficient equal to or smaller than that of the thickest cladding layer in the layered structure, such as GaN, Si, SiC, or the like (in this example, n-type GaN), is preferably used. According to the above-described embodiment, semiconductor light emitting elements were fabricated based on a sapphire substrate, a Si substrate, a SiC substrate, and a GaN substrate, and for each of the fabricated semiconductor elements, the efficiency of emission generated from the strained emission layer 3 with a constant current density due to inner-shell transition of a rare earth element (inner quantum efficiency) was measured. In the case of the GaN substrate, the inner quantum efficiency was 13%. In the case of the Si substrate, the inner quantum efficiency was 15%. In the case of the SiC substrate, the inner quantum efficiency was 15%. However, in the case of the sapphire substrate, the inner quantum efficiency was 8%, which was about a half of that obtained with the other substrates. This is thought to be because the strained emission layer 3 is subjected to a compressive strain due to a lattice mismatch with the n-type GaN underlying layer, and because of thermal strain which is caused mainly due to the difference in the thermal expansion coefficient between the sapphire substrate and the thickest layer (n-type GaN layer 2) is imposed on the strained emission layer 3 when the temperature of the layered structure is decreased from a crystal growth temperature of 700° C., on average, to room temperature. Since the sapphire substrate has a greater thermal expansion coefficient than that of the thickest layer (n-type GaN layer 2), thermal strain which is greater than a strain caused due to the difference in the lattice constant between the strained emission layer 3 and the n-type GaN layer 2 is imposed on the strained emission layer 3. As a result, a piezoelectric field generated in the strained emission layer 3 becomes large. The piezoelectric field functions to decrease the probability that an electron and a hole injected into the strained emission layer 3 are trapped by a rare earth element, and hence, the efficiency of emission generated due to inner-shell transition of the rare earth element is decreased.

On the other hand, in the case where GaN is used as the substrate, a strain other than strain caused by a lattice mismatch is not imposed on the strained emission layer 3. Thus, the piezoelectric field in the strained emission layer 3 is significantly smaller than that obtained when the sapphire substrate is used. In the case where Si or SiC, which have smaller thermal expansion coefficients than that of GaN, is used in the substrate, a tensile stress, which is not caused when the sapphire substrate is used, is imposed on the strained emission layer 3such that the strain caused due to a lattice mismatch is relaxed. Thus, the emission efficiency is thought to be improved as compared to the GaN substrate.

According to the present embodiment, as described above, uniform emission is achieved by using a conductive substrate. Further, the emission efficiency is improved by making a substrate, on which a layered structure including the strained emission layer 3 is formed, from a material which has a thermal expansion coefficient equal to or smaller than that of the thickest cladding layer in a layered structure formed thereon. These advantageous effects can be obtained not only in this embodiment but also in each of the following embodiments described below. Furthermore, the advantageous effects can be obtained even when the rare earth element added to the strained emission layer 3 is any of Er, Eu, Ho, Nd, Pr, Tm, and Yb.

When an electric current of 20 mA is applied to a semiconductor light emitting element produced according to the present invention, the semiconductor light emitting element operates as a white color LED which emits white light made from a mixture of blue and yellow light, which exhibits emission energy peaks at 2.70 eV, 2.31 eV, and 2.22 eV (corresponding to wavelengths of 460 nm, 537 nm, and 558 nm, respectively). This white color LED produces an emission output of 6.0 mW, which is about 10 times greater than that of a conventional MIS structure element including Er-doped GaN. Furthermore, the semiconductor light emitting element of the present invention has excellent temperature characteristics. Especially for each emission at 537 nm and 558 nm which are between the f-levels of the rare earth element Er, the wavelength shifts between room temperature and liquid nitrogen temperature is only a variation corresponding to an emission energy of about 2 meV.

The emission efficiency is determined based on the probability that a free electron and a free hole in a semiconductor (in this invention, the strained emission layer including In, such as InGaN, InGaNP, InGaAlN, InGaNSb, or the like) are trapped by a rare earth element because an inner-shell transition of a rare earth element is utilized for emission from the strained emission layer. Thus, based on the probability that a free electron and a free hole are trapped by a rare earth element, due to a non-uniform flow of an electric current in the strained emission layer 3, a sharp, high peak can be obtained as the emission efficiency distribution pattern, as compared with a conventional semiconductor light emitting element utilizing a band edge emission. Thus, according to the present invention, a conductive substrate (n-type GaN substrate 1) is used in such a semiconductor light emitting element which utilizes an inner-shell transition of a rare earth element, so that a flow of electric current (in-plane distribution of the electric current density) becomes uniform in an emission region of the strained light emitting layer 3. As a result, high emission efficiency is obtained as compared with a conventional semiconductor light emitting element.

According to the present invention, the conductive substrate is not limited to the n-type GaN substrate 1 of the present embodiment. Any conductive substrate can be used so long as an electrode can be formed on the back surface of the substrate (the surface of the substrate opposite to the surface on which the strained emission layer is formed), such as a conductive Si substrate, a conductive Ni substrate, or the like. Furthermore, in order to secure a uniform current flow in an emission region, the back surface electrode is formed such that a horizontal cross section of the back surface electrode covers substantially the entire horizontal cross section of the strained emission layer.

### EMBODIMENT 2

Next, a semiconductor light emitting element according to embodiment 2 of the present invention is described. In embodiment 2, the strained emission layer 3 is formed of GaN_{0.96}As_{0.04} containing Pr (praseodymium) so as to have a thickness of 20 Å. That is, embodiment 2 differs from embodiment 1 in the composition of the strained emission layer 3. In order to add the rare earth element Pr to the strained emission layer 3, a source gas containing Pr, (C₅H₅)₃Pr (i.e., Cp3Pr), is supplied during the formation of the GaN_{0.96}As_{0.04} strained emission layer 3. Under the same growth conditions as those for the Er-doped In_{0.35}Ga_{0.65}N strained emission layer described in embodiment 1, supply of TMI (trimethyl indium) is stopped while 500 cc of AsH₃ (arsine) is supplied, so as to form the Pr-doped GaN₀₉₆As_{0.04} layer. The other details of the structure of embodiment 2 are the same as those of the semiconductor light emitting element according to embodiment 1 shown in FIG. 1.

When an electric current of 20 mA is applied to the semiconductor light emitting element of embodiment 2, the semiconductor light emitting element operates as a multi color (blue/red) LED which emits blue light and red light, which exhibits emission energy peaks at 2.76 eV and 1.91 eV (corresponding to wavelengths of 450 nm and 650 nm, respectively). This multi color LED produces an emission output of 4.0 mW. The emission efficiency of the LED of embodiment 2 is about 6 times greater than that of a conventional MIS structure element including Er-doped GaN.

### EMBODIMENT 3

Next, a semiconductor light emitting element according to embodiment 3 of the present invention is described. In embodiment 3, the strained emission layer 3 is formed of GaN_{0.94}P_{0.06} containing Eu (europium) so as to have a thickness of 20 Å. That is, embodiment 3 differs from embodiment 1 in the composition of the strained emission layer 3. In order to add the rare earth element Eu to the strained emission layer 3, a source gas containing Eu, (C₁₁H₁₉O₂)₃Eu (i.e., DPM3Eu), is supplied during the formation of the GaN_{0.94}P_{0.06} strained emission layer 3. Under the same growth conditions as those for the Er-doped In_{0.35}Ga_{0.65}N strained emission layer described in embodiment 1, supply of TMI (trimethyl indium) is stopped while 500 cc of PH₃ (phosphine) is supplied, so as to form the Eu-doped GaN_{0.94}P_{0.06} layer. The other details of the structure of embodiment 3 are the same as those of the semiconductor light emitting element according to embodiment 1 shown in FIG. 1.

When an electric current of 20 mA is applied to the semiconductor light emitting element of embodiment 3, the semiconductor light emitting element operates as a multi color (blue/red) LED which emits blue light and red light, which exhibits emission energy peaks at 2.76 eV and 2.00 eV (corresponding to wavelengths of 450 nm and 621 nm, respectively). This multi color LED produced an emission output of 4.0 mW. The emission efficiency of the LED of embodiment 3 is about 6 times greater than that of a conventional MIS structure element including Er-doped GaN.

### EMBODIMENT 4

Next, a semiconductor light emitting element according to embodiment 4 of the present invention is described. In embodiment 4, the strained emission layer 3 is formed of In_{0.15}Ga_{0.85}N_{0.97}P_{0.03} containing Eu (europium) so as to have a thickness of 20 Å. That is, embodiment 4 differs from embodiment 3 in the composition of the strained emission layer 3. In order to add the rare earth element Eu to the strained emission layer 3, a source gas containing Eu, (C₁₁H,₁₉O₂)₃Eu (i.e., DPM3Eu), is supplied during the formation of the In_{0.15}Ga_{0.85}N_{0.97}P_{0.03} strained emission layer 3. Under the same growth conditions as those for the Eu-doped GaN_{0.94}P_{0.06} strained emission layer of embodiment 3, TMI (trimethyl indium) is supplied at 30 μmol/min, so as to form the Eu-doped In_{0.15}Ga_{0.85}N_{0.97}P_{0.03} layer. The other details of the structure of embodiment 4 are the same as those of the semiconductor light emitting element according to embodiment 1 shown in FIG. 1.

When an electric current of 20 mA is applied to the semiconductor light emitting element of embodiment 4, the semiconductor light emitting element operates as a multi color (blue/red) LED which emits blue light and red light, which exhibits emission energy peaks at 2.76 eV and 2.00 eV (corresponding to wavelengths of 450 nm and 621 nm, respectively). This multi color LED produces an emission output of 5.0 mW. The emission intensity of the LED of embodiment 4 is improved by 25% as a result of added In, as compared with the semiconductor light emitting element of embodiment 3.

### EMBODIMENT 5

Next, a semiconductor light emitting element according to embodiment 5 of the present invention is described. In embodiment 5, the strained emission layer 3 is formed of In_{0.35}Ga_{0.65}N containing Er (erbium), Pr (praseodymium), Eu (europium), and Tm (thulium) so as to have a thickness of 30 Å. In order to add the rare earth elements Pr, Eu, and Tm to the strained emission layer 3, source gases containing Pr, Eu, and Tm, (C₅H₅)₃Pr (i.e., Cp3Pr), (C₁₁H₁₉O₂)₃Eu (i.e., DPM3Eu), (C₁₁H₁₉O₂)₃Tm (i.e., DPM3Tm), respectively, are supplied during the formation of the Er-doped In_{0.35}Ga_{0.65}N strained emission layer 3 described in embodiment 1, so as to form an Er/Pr/Eu/Tm-doped In_{0.35}Ga_{0.65}N layer. The other details of the structure of embodiment 5 are the same as those of the semiconductor light emitting element according to embodiment 1 shown in FIG. 1.

When an electric current of 20 mA is applied to the semiconductor light emitting element of embodiment 5, the semiconductor light emitting element operates as a white color LED which emits white light made from a mixture of multiple colors, which exhibits emission energy peaks at 2.70 eV, 2.53 eV, 2.31 eV, and 2.22 eV, 2.00 eV, and 1.91 eV (corresponding to wavelengths of 460 nm, 490 nm, 537 nm, 558 nm, 621 nm, and 650 nm, respectively). This white color LED produced an emission output of 6.0 mW, which is substantially the same as that of the semiconductor light emitting element of embodiment 1. However, the color rendering characteristic of embodiment 5 is 95%, which is improved by about 5% as compared with the semiconductor light emitting element of embodiment 1. The color rendering characteristic of embodiment 5 is substantially the same as that obtained by a cathode ray tube which is used as a backlight of a liquid crystal display device. As a result, based on the white color LED of embodiment 5 of the present invention, a backlight which can produce a predetermined brightness without generating time lag and which has an excellent color rendering characteristic is produced.

A semiconductor light emitting element of the present invention includes, on a substrate, a first conductive semiconductor layer, a strained emission layer, and a second conductive semiconductor layer in this order. The strained emission layer contains an element other than constituent elements of the substrate, and a rare earth element. Due to the added element other than constituent elements of the substrate and a rare earth element, an amount of emission centers which are formed by rare earth elements is increased, so that the transfer efficiency of an injected current from the primary part of the emission layer to the rare earth element is increased. As a result, the semiconductor light emitting element of the present invention has high emission efficiency.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A semiconductor light emitting element, comprising:
a substrate;
a first conductive semiconductor layer formed on the substrate;
a strained emission layer formed on the first conductive semiconductor layer; and
a second conductive semiconductor layer formed on the strained emission layer,
wherein the strained emission layer includes: an element other than a constituent element of the substrate; and a rare earth element.

2. A semiconductor light emitting element according to claim 1, wherein the substrate is an electrically conductive substrate.

3. A semiconductor light emitting element according to claim 2, wherein the rare earth element included in the strained emission layer is at least one selected from a group consisting of Er, Eu, Ho, Nd, Pr, Tm, and Yb.

4. A semiconductor light emitting element according to claim 1, wherein the element other than a constituent element of the substrate is at least one of a III-group element and a V-group element.

5. A semiconductor light emitting element according to claim 4, wherein the strained emission layer is formed of InₓGa₁₋ₓN where 0<x<0.5.

6. A semiconductor light emitting element according to claim 5, wherein the rare earth element included in the strained emission layer is at least one selected from a group consisting of Er, Eu, Ho, Nd, Pr, Tm, and Yb.

7. A semiconductor light emitting element according to claim 4, wherein the strained emission layer is formed of GaN₁₋ₓAsₓ where 0<x<0.1.

8. A semiconductor light emitting element according to claim 7, wherein the rare earth element included in the strained emission layer is at least one selected from a group consisting of Er, Eu, Ho, Nd, Pr, Tm, and Yb.

9. A semiconductor light emitting element according to claim 4, wherein the strained emission layer is formed of GaN₁₋ₓPₓ where 0<x≦0.15.

10. A semiconductor light emitting element according to claim 9, wherein the rare earth element included in the strained emission layer is at least one selected from a group consisting of Er, Eu, Ho, Nd, Pr, Tm, and Yb.

11. A semiconductor light emitting element according to claim 4, wherein the strained emission layer is formed of GaN₁₋ₓAsₓ or GaN₁₋ₓPₓ and contains In.

12. A semiconductor light emitting element according to claim 11, wherein the rare earth element included in the strained emission layer is at least one selected from a group consisting of Er, Eu, Ho, Nd, Pr, Tm, and Yb.

13. A semiconductor light emitting element according to claim 4, wherein the rare earth element included in the strained emission layer is at least one selected from a group consisting of Er, Eu, Ho, Nd, Pr, Tm, and Yb.

14. A semiconductor light emitting element according to claim 1, wherein the rare earth element included in the strained emission layer is at least one selected from a group consisting of Er, Eu, Ho, Nd, Pr, Tm, and Yb.

15. A method for producing a semiconductor light emitting element, comprising steps of:
forming a first conductive nitride semiconductor layer having a first conduction type, at a first growth temperature, on a nitride semiconductor substrate having the first conduction type;
forming a strained emission layer, at a second growth temperature which is different from the first growth temperature, on the first conductive nitride semiconductor layer; and
forming a second conductive nitride semiconductor layer having a second conduction type, at a third growth temperature which is different from the first and second growth temperatures, on the strained emission layer.
